(19) United States
(12) Patent Application Publication
(10) Pub. No.: US 2023/0180524 A1
(43) Pub. Date: Jun. 8, 2023

(54) DISPLAY DEVICE

(71) Applicant: Samsung Display Co., Ltd., Yongin-si (KR)

(72) Inventors: KWANGHYUN KIM, Hwaseong-si (KR); HEONSIK HA, Hwaseong-si (KR); YUNG BIN CHUNG, Yongin-si (KR)

(21) Appl. No.: 17/820,090

(22) Filed: Aug. 16, 2022

(30) Foreign Application Priority Data
Dec. 2, 2021 (KR) 10-2021-0171161

(51) Int. Cl. H01L 27/32; H01L 51/52; H01L 51/56

(52) U.S. Cl. CPC H01L 27/3246; H01L 51/5253; H01L 51/56; H01L 27/322; H01L 2227/323

(57) ABSTRACT

A display device includes a substrate including first, second, and third light emitting areas and a light blocking area surrounding the first, second, and third light emitting areas, a driving element on the substrate, a light emitting element respectively in each of the first, second, and third light emitting areas on the driving element and electrically connected to the driving element, a color conversion layer including a first color conversion pattern, a second color conversion pattern, and a transmission pattern in the first, second, and third light emitting areas on the light emitting element, respectively, and a capping layer on the color conversion layer and including a silicon compound. A ratio of a hydrogen content of an N—H bond to a hydrogen content of a Si—H bond of the capping layer is about 16 or more.

### CROSS-REFERENCE TO RELATED APPLICATION

This application claims priority to and the benefit of Korean Patent Application No. 10-2021-0171161, filed on Dec. 2, 2021, the entire content of which is hereby incorporated by reference for all purposes as if fully set forth herein.

### BACKGROUND

### 1. Field

Embodiments of the present disclosure relate to a display device. For example, embodiments of the present disclosure relate to a display device that provides visual information.

### 2. Description of the Related Art

A flat panel display device is being used as a display device replacing a cathode ray tube display device due to characteristics such as light weight and thinness. Representative examples of such flat panel display devices include a liquid crystal device (LCD) and an organic light emitting display device (OLED).

Recently, an organic light emitting display device including an organic light emitting element and a color conversion layer has been studied. The color conversion layer may convert a wavelength of light provided from the organic light emitting element. Accordingly, the organic light emitting display device may emit light having a color different from a color of an incident light.

### SUMMARY

Embodiments of the present disclosure provide a display device having improved display quality.

A display device according to an embodiment of the present disclosure may include a substrate including a first light emitting area, a second light emitting area, and a third light emitting area, and a light blocking area surrounding the first light emitting area, the second light emitting area, and the third light emitting area, a driving element on the substrate, a light emitting element respectively on the driving element in each of the first light emitting area, the second light emitting area, and the third light emitting area and electrically connected to the driving element, a color conversion layer including a first color conversion pattern on the light emitting element in the first light emitting area, a second color conversion pattern on the light emitting element in the second light emitting area, and a transmission pattern on the light emitting element in the third light emitting area, and a capping layer on the color conversion layer and including a silicon compound. A ratio of a hydrogen content of an N—H bond to a hydrogen content of a Si—H bond of the capping layer may be about 16 or more.

In an embodiment, the hydrogen content of the Si—H bond of the capping layer may be about 0.8 atomic percent (at %) or less.

In an embodiment, a total hydrogen content of the capping layer may be about 14.3 at % or less.

In an embodiment, the silicon compound may include at least one selected from the group consisting of silicon nitride (SiNₓ) and silicon oxynitride (SiON).

In an embodiment, the display device may further include a color filter layer on the color conversion layer and including a first color filter, a second color filter, and a third color filter overlapping the first color conversion pattern, the second color conversion pattern, and the transmission pattern, respectively.

In an embodiment, the display device may further include a passivation layer on the color filter layer, the passivation layer including at least one selected from the group consisting of an organic material and an inorganic material.

In an embodiment, the display device may further include a bank layer between the first color conversion pattern and the second color conversion pattern, between the second color conversion pattern and the transmission pattern, and overlapping the light blocking area.

In an embodiment, the capping layer may be located along a profile of each of the color conversion layer and the bank layer.

In an embodiment, the driving element may include a metal oxide semiconductor.

A display device according to an embodiment of the present disclosure may include a substrate including a first light emitting area, a second light emitting area, and a third light emitting area, and a light blocking area surrounding the first light emitting area, the second light emitting area, and the third light emitting area, a driving element on the substrate, a light emitting element respectively on the driving element in each of the first light emitting area, the second light emitting area, and the third light emitting area and electrically connected to the driving element, a color conversion layer including a first color conversion pattern on the light emitting element in the first light emitting area, a second color conversion pattern on the light emitting element in the second light emitting area, and a transmission pattern on the light emitting element in the third light emitting area, and a capping layer including: a first passivation layer on the color conversion layer, the passivation layer including a metal oxide, and a second passivation layer on the first passivation layer, the second passivation layer including a silicon compound.

In an embodiment, the metal oxide may include at least one selected from the group consisting of aluminum oxide (Al₂O₃), titanium oxide (TiO₂), tantalum oxide (Ta₂O₅), hafnium oxide (HfO₂), and zinc oxide (ZnO₂).

In an embodiment, the silicon compound may include at least one selected from the group consisting of silicon nitride and silicon oxynitride.

In an embodiment, a thickness of the first passivation layer may be different from a thickness of the second passivation layer.

In an embodiment, the thickness of the second passivation layer may be greater than the thickness of the first passivation layer.

In an embodiment, the thickness of the first passivation layer may be about 10 nm or less, and the thickness of the second passivation layer may be about 500 nm or less.

In an embodiment, the display device may further include a color filter layer on the color conversion layer, the color filter layer including a first color filter, a second color filter, and a third color filter overlapping the first color conversion pattern, the second color pattern, and the transmission pattern, respectively.

In an embodiment, the display device may further include a third passivation layer on the color filter layer, the third passivation layer including at least one selected from the group consisting of an organic material and an inorganic material.

In an embodiment, the display device may further include a bank layer respectively between the first color conversion pattern and the second color conversion pattern, between the second color conversion pattern, and the transmission pattern, and overlapping the light blocking area.

In an embodiment, the capping layer may be located along a profile of each of the color conversion layer and the bank layer.

In an embodiment, the driving element may include a metal oxide semiconductor.

In a display device according to an embodiment of the present disclosure, a capping layer including silicon nitride and/or silicon oxynitride may be on a color conversion layer that converts light emitted from a light emitting element into light having a set or specific wavelength. A hydrogen content of an N—H bond of the capping layer may be relatively higher than a hydrogen content of a Si—H bond. Accordingly, diffusion of hydrogen in the capping layer to a driving element (e.g., a thin film transistor) including a metal oxide semiconductor may be prevented or reduced. In addition, as the hydrogen of the capping layer diffuses into the driving element, an influence on the characteristics of the driving element may be minimized or reduced.

### BRIEF DESCRIPTION OF THE DRAWINGS

Illustrative, non-limiting embodiments of the present disclosure will be more clearly understood from the following detailed description in conjunction with the accompanying drawings.

FIG. 1 is a plan view illustrating a display device according to an embodiment.

FIG. 2 is a cross-sectional view taken along line I-I′ of FIG. 1.

FIG. 3 is a cross-sectional view illustrating a color conversion layer of the display device of FIG. 2.

FIG. 4 is a diagram illustrating the results of measuring the thermal stability of the N—H bond and the Si—H bond.

FIGS. 5-12 are cross-sectional views illustrating a method of manufacturing the display device of FIG. 2.

FIG. 13 is a diagram illustrating a change amount of a threshold voltage of a thin film transistor according to a comparative example.

FIG. 14 is a diagram illustrating a change amount of a threshold voltage of a thin film transistor according to an embodiment.

FIG. 15 is a cross-sectional view illustrating a display device according to another embodiment.

### DETAILED DESCRIPTION

Hereinafter, embodiments of the present disclosure will be explained in more detail with reference to the accompanying drawings. The same reference numerals are used for the same components in the drawings, and redundant descriptions of the same components may not be repeated.

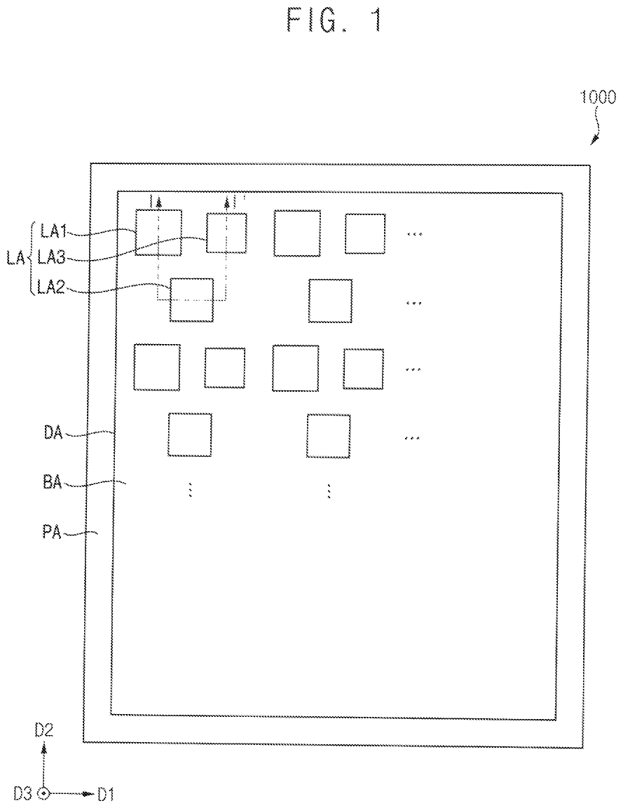

FIG. 1 is a plan view illustrating a display device according to an embodiment.

Referring to FIG. 1, the display device 1000 according to an embodiment may include a display area DA and a peripheral area PA. The display area DA may denote an area that displays an image. The peripheral area PA may denote an area that is not designed to display an image. The peripheral area PA may be located around the display area DA. For example, the peripheral area PA may surround the display area DA.

The display area DA may include a plurality of light emitting areas LA and a light blocking area BA. Each of the light-emitting areas LA may include a first light emitting area LA1, a second light emitting area LA2, and a third light emitting area LA3.

Each of the first light emitting area LA1, the second light emitting area LA2, and the third light emitting area LA3 may be an area in which light emitted from a light emitting element is emitted to an outside of the display device 1000. For example, the first light emitting area LA1 may emit a first light, the second light emitting area LA2 may emit a second light, and the third light emitting area LA3 may emit a third light. In an embodiment, the first light may be red light, the second light may be green light, and the third light may be blue light. However, the configuration of the present disclosure is not limited thereto. For example, the light emitting areas LA may be combined to emit yellow, cyan, and/or magenta lights.

The light emitting areas LA may emit light of four or more colors. For example, the light emitting areas LA may be combined to further emit at least one selected from yellow, cyan, and magenta lights in addition to red, green, and blue lights. In addition, the light emitting areas LA may be combined to further emit white light.

In a plan view, each of the first light emitting area LA1, the second light emitting area LA2, and the third light emitting area LA3 may be repeatedly arranged along a row direction and a column direction. For example, in the plan view, each of the first light emitting area LA1, the second light emitting area LA2, and the third light emitting area LA3 may be repeatedly arranged along a first direction D1 and a second direction D2 perpendicular (e.g., substantially perpendicular) to the first direction D1. A third direction D3 may be perpendicular (e.g., substantially perpendicular) to the first direction D1 and the second direction D2. In an embodiment, in the plan view, the first light emitting area LA1 and the third light emitting area LA3 may be repeatedly arranged in a first row of the display area DA, and the second light emitting area LA2 may be repeatedly arranged in a second row of the display area DA.

The first light emitting area LA1, the second light emitting area LA2, and the third light emitting area LA3 may have different sizes relative to each other. In an embodiment, an area of the first light emitting area LA1 that may emit red light may be larger than an area of each of the second light emitting area LA2 that may emit green light and the third light emitting area LA3 that may emit blue light. In this case, the area of the second light emitting area LA2 may be larger than the area of the third light emitting area LA3. However, the configuration of the present disclosure is not limited thereto. In another embodiment, the area of the second light emitting area LA2 that may emit green light may be larger than the area of each of the first light emitting area LA1 that may emit red light and the third light emitting area LA3 that may emit blue light. In this case, the area of the first light emitting area LA1 may be larger than the area of the third light emitting area LA3.

Each of the first light emitting area LA1, the second light emitting area LA2, and the third light emitting area LA3 may independently have a triangular planar shape, a rectangular planar shape, a circular planar shape, a track-type planar shape, an elliptical planar shape, or the like. In an embodiment, each of the first light emitting area LA1, the second light emitting area LA2, and the third light emitting area LA3 may have a rectangular planar shape.

The light blocking area BA may be between the first light emitting area LA1, the second light-emitting area LA2, and the third light emitting area LA3. For example, in the plan view, the light blocking area BA may surround the first light emitting area LA1, the second light emitting area LA2, and the third light emitting area LA3. The light blocking area BA may not emit light.

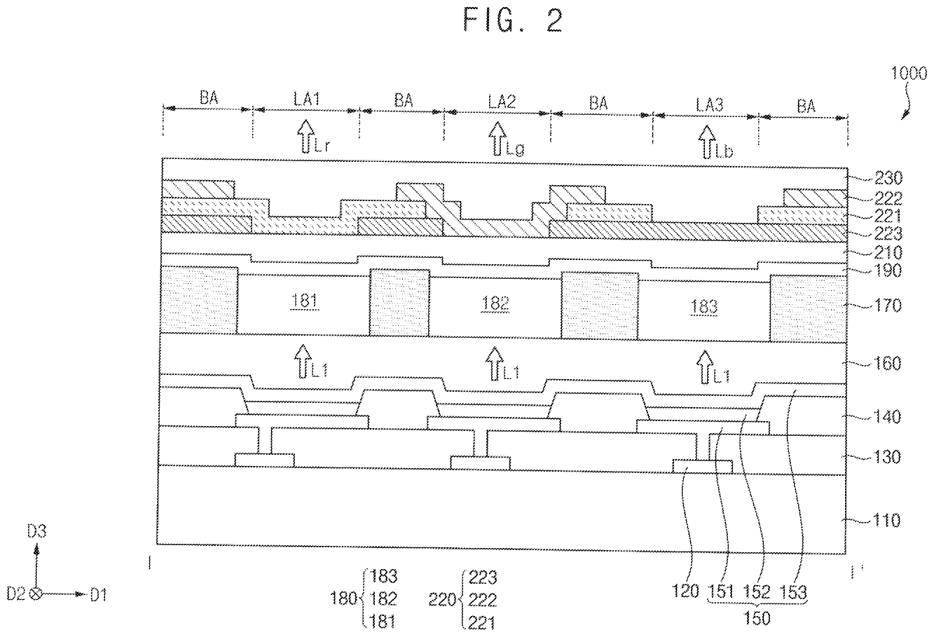

FIG. 2 is a cross-sectional view taken along line I-I′ of FIG. 1.

Referring to FIG. 2, the display device 1000 according to an embodiment of the present disclosure may include a substrate 110, a driving element 120, an insulating structure 130, a pixel defining layer 140, a light emitting element 150, an encapsulation structure 160, a bank layer 170, a color conversion layer 180, a capping layer 190, a low refractive index layer 210, a color filter layer 220, and a passivation layer 230. Here, the light emitting element 150 may include a lower electrode 151, a light emitting layer 152, and an upper electrode 153.

The substrate 110 may include a transparent material and/or an opaque material. The substrate 110 may be formed of a transparent resin substrate. Examples of the transparent resin substrate may include a polyimide substrate and the like. In this case, the polyimide substrate may include a first organic layer, a first barrier layer, a second organic layer, and the like. In some embodiments, the substrate 110 may include a quartz substrate, a synthetic quartz substrate, a calcium fluoride substrate, a fluorine-doped quartz substrate, a soda-lime substrate, a non-alkali glass substrate, and/or the like. The foregoing may be used alone or in combination with each other.

The driving element 120 may be on the substrate 110. In an embodiment, the driving element 120 may include a thin film transistor. For example, the driving element 120 may include amorphous silicon, polycrystalline silicon, or a metal oxide semiconductor.

The metal oxide semiconductor may include a binary compound (ABₓ), a ternary compound (ABₓC_{y}), a quaternary compound (ABₓC_{y}D_{z}), and/or the like containing indium (In), zinc (Zn), gallium (Ga), tin (Sn), titanium (Ti), aluminum (Al), hafnium (Hf), zirconium (Zr), magnesium (Mg), and/or the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and/or the like. The foregoing may be used alone or in combination with each other.

The insulating structure 130 may be on the substrate 100. The insulating structure 130 may cover the driving element 120. The insulating structure 130 may include a combination of at least one inorganic insulating layer and at least one organic insulating layer. For example, the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), and/or the like. In addition, the organic insulating layer may include a photoresist, a polyacryl-based resin, a polyimide-based resin, a polyamide-based resin, a siloxane-based resin, an acryl-based resin, an epoxy-based resin, and/or the like. Each of the foregoing may be used alone or in combination with each other.

The lower electrode 151 may be respectively in each of the first light emitting area LA1, the second light emitting area LA2, and the third light emitting area LA3 on the insulating structure 130. The lower electrode 151 may be connected to the driving element 120 through a contact hole formed by removing a portion of the insulating structure 130. For example, the lower electrode 151 may include a metal, an alloy, a metal nitride, a conductive metal oxide, a transparent conductive material, and/or the like. The foregoing may be used alone or in combination with each other. For example, the lower electrode 151 may act as an anode.

The pixel defining layer 140 may be in the light blocking area BA on the insulating structure 130 and the lower electrode 151. The pixel defining layer 140 may cover both sides of the lower electrode 151 and expose an upper surface of the lower electrode 151. The pixel defining layer 140 may include an organic material and/or an inorganic material. In an embodiment, the pixel defining layer 140 may include an organic material. Examples of the organic material that can be used for the pixel defining layer 140 may include photoresist, polyacrylic resin, polyimide-based resin, polyamide-based resin, siloxane-based resin, acrylic-based resin, epoxy-based resin, and/or the like. The foregoing may be used alone or in combination with each other.

The light emitting layer 152 may be on the lower electrode 151. For example, a hole provided from the lower electrode 151 and an electron provided from the upper electrode 153 combine in the light emitting layer 152 to form an exciton, and as the exciton changes from an excited state to a ground state, the light emitting layer 152 may emit light. The light emitting layer 152 may emit light having a set or specific color (e.g., red, green, and/or blue). In an embodiment, the light emitting layer 152 may emit blue light L1.

The upper electrode 153 may be on the light emitting layer 152 and the pixel defining layer 140. The upper electrode 153 may be entirely in the first light emitting area LA1, the second light emitting area LA2, and the third light emitting area LA3 and the light blocking area BA. For example, the upper electrode 153 may include a metal, an alloy, a metal nitride, a conductive metal oxide, a transparent conductive material, and/or the like. The foregoing may be used alone or in combination with each other. For example, the upper electrode 153 may act as a cathode.

Accordingly, the light emitting element 150 including the lower electrode 151, the light emitting layer 152, and the upper electrode 153 may be on the substrate 110. The light emitting element 150 may be in each of the first light emitting area LA1, the second light emitting area LA2, and the third light emitting area LA3. The light emitting element 150 may be electrically connected to the driving element 120. In an embodiment, the light emitting element 150 may include a blue light emitting element emitting blue light L1.

The encapsulation structure 160 may be on the upper electrode 153. The encapsulation structure 160 may prevent or reduce penetration of impurities, moisture, and/or the like into the light emitting element 150 from an outside. The encapsulation structure 160 may include at least one inorganic encapsulation layer and at least one organic encapsulation layer. For example, the inorganic encapsulation layer may include silicon oxide, silicon nitride, silicon oxynitride, and/or the like, and the organic encapsulation layer may include a cured polymer such as polyacrylate.

The bank layer 170 may be on the encapsulation structure 160. The bank layer 170 may overlap a portion of the light blocking area BA. The bank layer 170 may surround the color conversion layer 180. A space for accommodating an ink composition may be formed in the bank layer 170 in the process of forming the color conversion layer 180. Accordingly, in the plan view, the bank layer 170 may have a grid shape or a matrix shape.

For example, the bank layer 170 may include an organic material such as an epoxy-based resin, a phenolic resin, an acrylic-based resin, a silicone-based resin, and/or the like. The foregoing may be used alone or in combination with each other. In an embodiment, the bank layer 170 may further include a light blocking material to serve as a black matrix. For example, at least a portion of the bank layer 170 may further include a light blocking material such as a pigment, a dye, and/or carbon black.

The color conversion layer 180 may be on the encapsulation structure 160. The color conversion layer 180 may convert light emitted from the light emitting element 150 into light having a set or specific wavelength.

The color conversion layer 180 may include a first color conversion pattern 181, a second color conversion pattern 182, and a transmission pattern 183. The first color conversion pattern 181 may be in the first light emitting area LA1, the second color conversion pattern 182 may be in the second light emitting area LA2, and the transmission pattern 183 may be in the third light emitting area LA3.

The first color conversion pattern 181 may convert the light L1 (e.g., blue light) emitted from the light emitting element 150 into light Lr of a first color. The second color conversion pattern 182 may convert the light L1 emitted from the light emitting element 150 into light Lg of a second color. The transmission pattern 183 may transmit the light L1 emitted from the light emitting element 150. In an embodiment, the first color may be red, and the second color may be green. In addition, the transmission pattern 183 may transmit the blue light Lb. However, the present disclosure is not limited thereto.

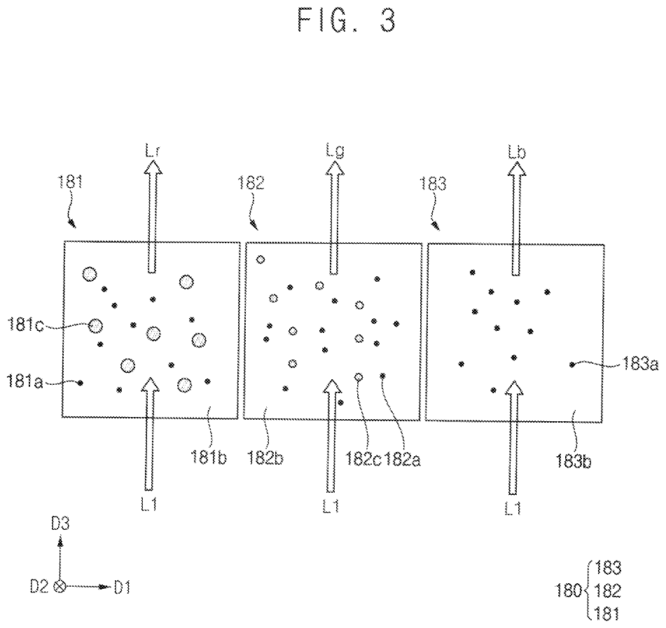

FIG. 3 is a cross-sectional view illustrating a color conversion layer of the display device of FIG. 2.

Referring to FIGS. 2 and 3, the first color conversion pattern 181 may include first quantum dots 181c that are excited by the light L1 emitted from the light emitting element 150 and emit the light Lr of the first color. In addition, the first color conversion pattern 181 may further include a first photosensitive polymer 181b in which first scattering particles 181a area dispersed.

The second conversion pattern 182 may include second quantum dots 182c that area excited by the light L1 emitted from the light emitting element 150 and emit the light Lg of the second color. In addition, the second color conversion pattern 182 may further include a second photosensitive polymer 182b in which second scattering particles 182a are dispersed.

The transmission pattern 183 may transmit the light L1 emitted from the light emitting element 150 to emit blue light Lb. In addition, the transmission pattern 183 may include a third photosensitive polymer 183b in which third scattering particles 183a are dispersed.

For example, each of the first photosensitive polymer 181b, the second photosensitive polymer 182b, and the third photosensitive polymer 183b may include an organic material having light transmittance, such as a silicone resin, an epoxy resin, and/or the like. The first scattering particle 181a, the second scattering particle 182a, and the third scattering particle 183a may scatter and emit light emitted from the light emitting element 150. In addition, the first scattering particle 181a, the second scattering particle 182a, and the third scattering particle 183a may include the same material.

Accordingly, the first light emitting area LA1 may emit the red light Lr, the second light emitting area LA2 may emit the green light Lg, and the third light emitting area LA3 may emit the blue light Lb.

Referring back to FIG. 2, the capping layer 190 may be on the bank layer 170 and the color conversion layer 180. The capping layer 190 may be entirely in the first light emitting area LA1, the second light emitting area LA2, and the third light emitting area LA3 and the light blocking area BA. The capping layer 190 may serve to prevent or reduce permeation of moisture into the color conversion layer 180 to thereby prevent or reduce deterioration of the color conversion layer 180.

In an embodiment, the capping layer 190 may be located along a profile of each of the bank layer 170 and the color conversion layer 180. For example, the capping layer 190 may have a substantially uniform thickness along the profile of each of the bank layer 170 and the color conversion layer 180. In another embodiment, the capping layer 190 may have a flat upper surface without forming a step around the bank layer 170 and the color conversion layer 180 to cover each of the bank layer 170 and the color conversion layer 180 on the bank layer 170 and the color conversion layer 180.

The capping layer 190 may include a silicon compound. In an embodiment, the capping layer 190 may include silicon nitride (SiNₓ), silicon oxynitride (SiON), and the like. The foregoing may be used alone or in combination with each other.

When the capping layer 190 includes silicon nitride, silicon oxynitride, and/or the like, a hydrogen content of an N—H bond of the capping layer 190 may be relatively higher than a hydrogen content of a Si—H bond. In an embodiment, when the capping layer 190 includes silicon nitride, a ratio of the hydrogen content of the N—H bond to the hydrogen content of the Si—H bond of the capping layer 190 may be about 16 or more. In this case, the hydrogen content of the N—H bonds of the capping layer 190 may be about 13.5 atomic percent (at %) or more, and the hydrogen content of the Si—H bonds of the capping layer 190 may be about 0.8 at % or less. Accordingly, the total hydrogen content of the capping layer 190 may be about 14.3 at % or less.

Accordingly, the capping layer 190 may further perform a function of preventing or reducing the diffusion of hydrogen in the capping layer 190 to the driving element 120.

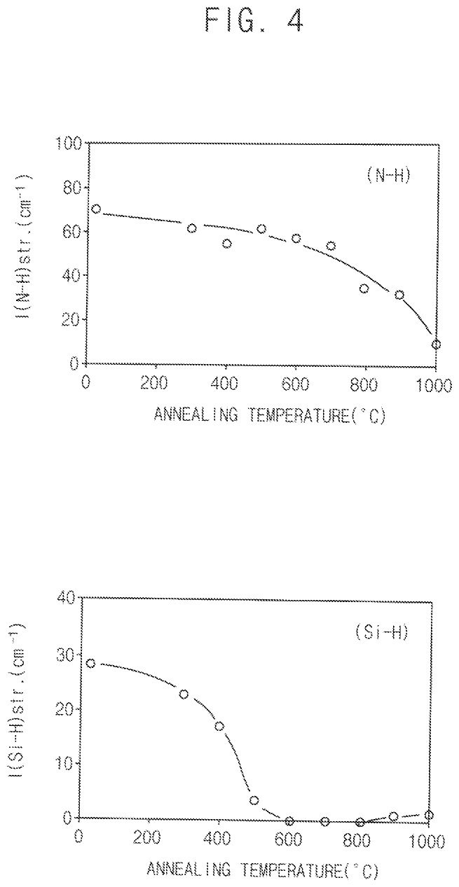

FIG. 4 is a diagram illustrating the results of measuring the thermal stability of the N—H bond and the Si—H bond.

Referring to FIG. 4, the thermal stability of the N—H bond is higher than the thermal stability of the Si—H bond. Therefore, as described above, when the ratio of the hydrogen content of the N—H bond to the hydrogen content of the Si—H bond of the capping layer 190 is about 16 or more, hydrogen in the capping layer 190 may not be easily separated. In this case, diffusion of hydrogen of the capping layer 190 into the driving element 120 (e.g., a thin film transistor) may be prevented or reduced.

Referring back to FIG. 2, the low refractive index layer 210 may be on the capping layer 190. The low refractive index layer 210 may be entirely in the first light emitting area LA1, the second light emitting area LA2, and the third light emitting area LA3 and the light blocking area BA. The low refractive index layer 210 may have a relatively low refractive index. For example, the refractive index of the low refractive index layer 210 may be lower than the refractive index of the color conversion layer 180. The low refractive index layer 210 may include an organic material. For example, the low refractive index layer 210 may include an organic polymer material including silicon.

The color filter layer 220 may be on the low refractive index layer 210. The color filter layer 220 may selectively transmit light having a set or specific wavelength.

The color filter layer 220 includes a first color filter 221, a second color filter 222, and a second color filter 221 overlapping the first color conversion pattern 181, the second color conversion pattern 182, and the transmission pattern 183, respectively. Three color filters 223 may be included. The colors of the light Lr, Lg, and Lb emitted from the first light emitting area LA1, the second light emitting area LA2, and the third light emitting area LA3 may be determined by the first color filter 221, the second color filter 222, and the third color filter 223.

A first portion of the first color filter 221 may overlap the first light emitting area LA1, and a second portion of the first color filter 221 may partially overlap the light blocking area BA. For example, the first color filter 221 may transmit red light Lr and block lights having a color different from a color of red light Lg.

A first portion of the second color filter 222 may overlap the second light emitting area LA2, and a second portion of the second color filter 222 may partially overlap the light blocking area BA. For example, the second color filter 222 may transmit green light Lg and block or reduce transmission of lights having a color different from a color of green light Lg.

A first portion of the third color filter 223 may overlap the third light emitting area LA3, and a second portion of the third color filter 223 may overlap the light blocking area BA. For example, the third color filter 223 may transmit the blue light Lb and block or reduce transmission of lights having a color different from a color of the blue light Lb.

The passivation layer 230 may be on the color filter layer 220. The passivation layer 230 may be entirely in the first light emitting area LA1, the second light emitting area LA2, and the third light emitting area LA3 and the light blocking area BA. The passivation layer 230 may cover the color filter layer 220. For example, the passivation layer 230 may include an inorganic material or an organic material. Examples of the inorganic material that can be used as the passivation layer 230 may include silicon oxide, silicon nitride, silicon oxynitride, and the like. The foregoing may be used alone or in combination with each other.

In FIG. 2, the display device 1000 of the present disclosure has a single substrate structure as an example, but the present disclosure is not limited thereto. For example, the display device 1000 of the present disclosure may have a structure including two substrates.

Hydrogen in a capping layer that protects a color conversion layer, is on the color conversion layer, and includes silicon nitride and/or silicon oxynitride may be diffused into a thin film transistor including a metal oxide semiconductor. In this case, hydrogen of the capping layer may diffuse into the thin film transistor and affect characteristics of the thin film transistor. Accordingly, the reliability of the thin film transistor may be reduced.

In the display device 1000 according to an embodiment of the present disclosure, the capping layer 190 including silicon nitride and/or silicon oxynitride may be on the color conversion layer 180 that converts light emitted from the light emitting element 150 into light having a set or specific wavelength. In this case, the hydrogen content of the N—H bond of the capping layer 190 may be relatively higher than the hydrogen content of the Si—H bond. Accordingly, diffusion of hydrogen of the capping layer 190 into the driving element 120 (e.g., a thin film transistor) including a metal oxide semiconductor may be prevented or reduced. In addition, as hydrogen of the capping layer 190 diffuses into the driving element 120, an influence on the characteristics of the driving element 120 may be minimized or reduced.

However, although the display device 1000 of the present disclosure is limited to an organic light emitting display device (OLED), the configuration of the present disclosure is not limited thereto. In other embodiments, the display device 1000 may include a liquid crystal display device (LCD), a field emission display device (FED), a plasma display device (PDP), an electrophoretic display device (EPD), a quantum dot display device, and/or an inorganic light emitting display device.

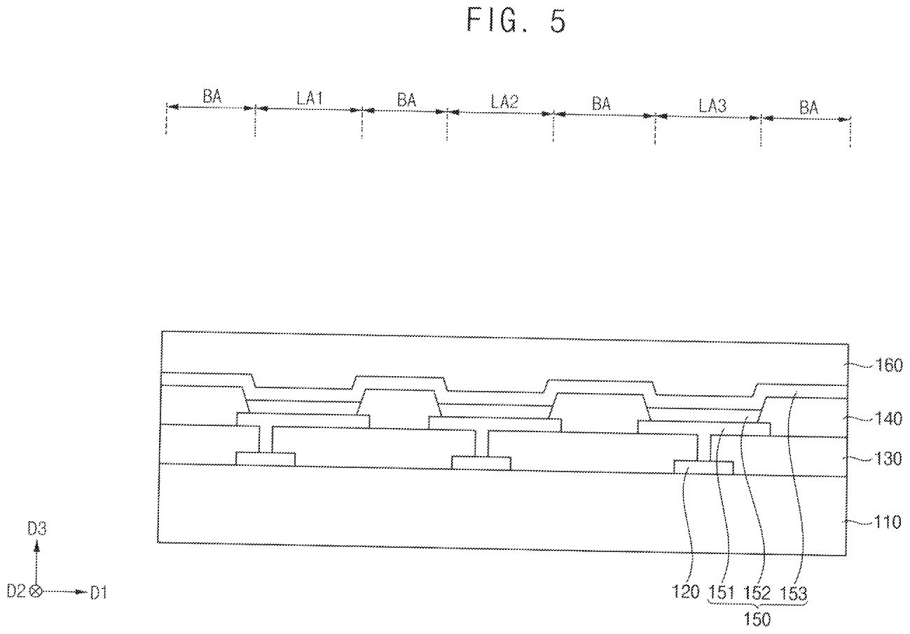

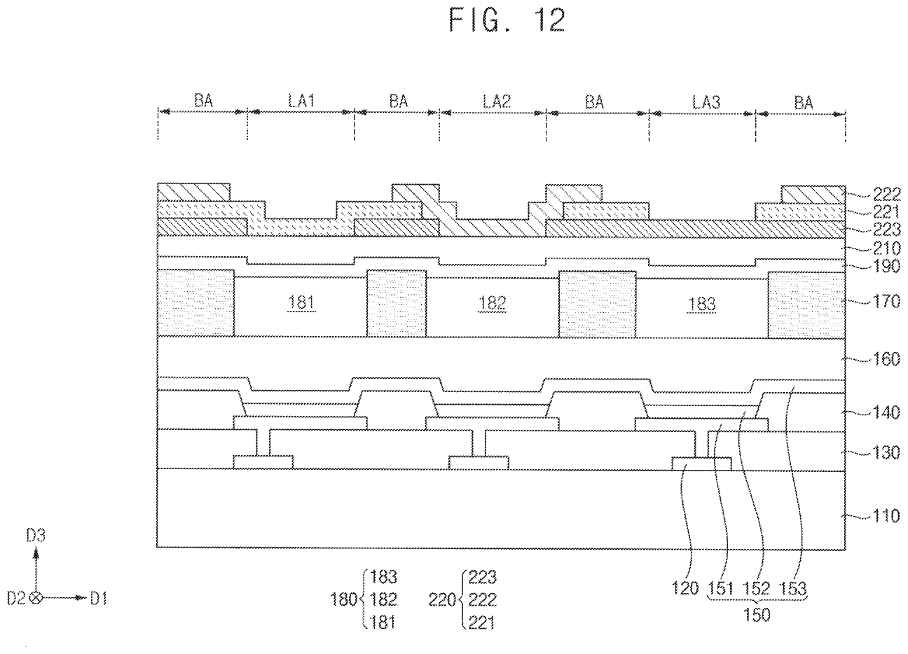

FIGS. 5-12 are cross-sectional views illustrating a method of manufacturing the display device of FIG. 2.

Referring to FIG. 5, the driving element 120 may be formed on the substrate 110. The substrate 110 may include a transparent material and/or an opaque material. For example, the substrate 110 may be formed of a transparent resin substrate.

For example, the driving element 120 may be formed using amorphous silicon, crystalline silicon, or a metal oxide semiconductor. In an embodiment, the driving element 120 may be formed using a metal oxide semiconductor.

The insulating structure 130 may be formed on the substrate 110. The insulating structure 130 may be entirely formed in the first light emitting area LA1, the second light emitting area LA2, and the third light emitting area LA3 and the light blocking area BA. The insulating structure 130 may cover the driving element 120. For example, the insulating structure 130 may be formed using at least one inorganic insulating layer and at least one organic insulating layer.

The lower electrode 151 may be formed in each of the first light emitting area LA1, the second light emitting area LA2, and the third light emitting area LA3 on the insulating structure 130. The lower electrode 151 may be connected to the driving element 120 through a contact hole formed by removing a portion of the insulating structure 130. For example, the lower electrode 151 may be formed using a metal, an alloy, a metal nitride, a conductive metal oxide, a transparent conductive material, and/or the like.

The pixel defining layer 140 may be formed in the light blocking area BA on the insulating structure 130 and the lower electrode 151. The pixel defining layer 140 may have an opening exposing a portion of the upper surface of the lower electrode 151. The pixel defining layer 140 may be formed using an organic material and/or an inorganic material.

The light emitting layer 152 may be formed on the lower electrode 151. For example, the light emitting layer 152 may be formed inside the opening of the pixel defining layer 140. The light emitting layer 152 may be formed using a low molecular weight organic compound and/or a high molecular weight organic compound.

The upper electrode 153 may be formed on the light emitting layer 152 and the pixel defining layer 140. The upper electrode 153 may be entirely formed in the first light emitting area LA1, the second light emitting area LA2, and the third light emitting area LA3 and the light blocking area BA. For example, the upper electrode 153 may be formed using a metal, an alloy, a metal nitride, a conductive metal oxide, a transparent conductive material, and/or the like.

Accordingly, the light emitting element 150 including the lower electrode 151, the light emitting layer 152, and the upper electrode 153 may be formed in each of the first light emitting area LA1, the second light emitting area LA2, and the third light emitting area LA3 on the substrate 110.

The encapsulation structure 160 may be formed on the upper electrode 153. The encapsulation structure 160 may be entirely formed in the first light emitting area LA1, the second light emitting area LA2, and the third light emitting area LA3 and the light blocking area BA. For example, the encapsulation structure 160 may be formed using at least one inorganic encapsulation layer and at least one organic encapsulation layer.

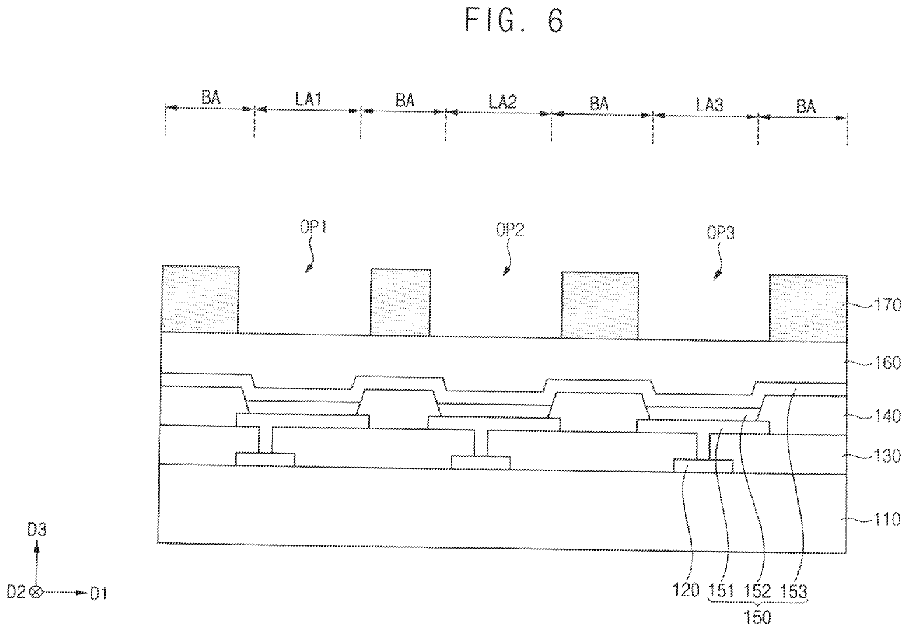

Referring to FIG. 6, the bank layer 170 may be formed on the encapsulation structure 160. In some embodiments, the bank layer 170 may be formed to overlap the light blocking area BA. For example, the bank layer 170 may be formed using an organic material and/or the like.

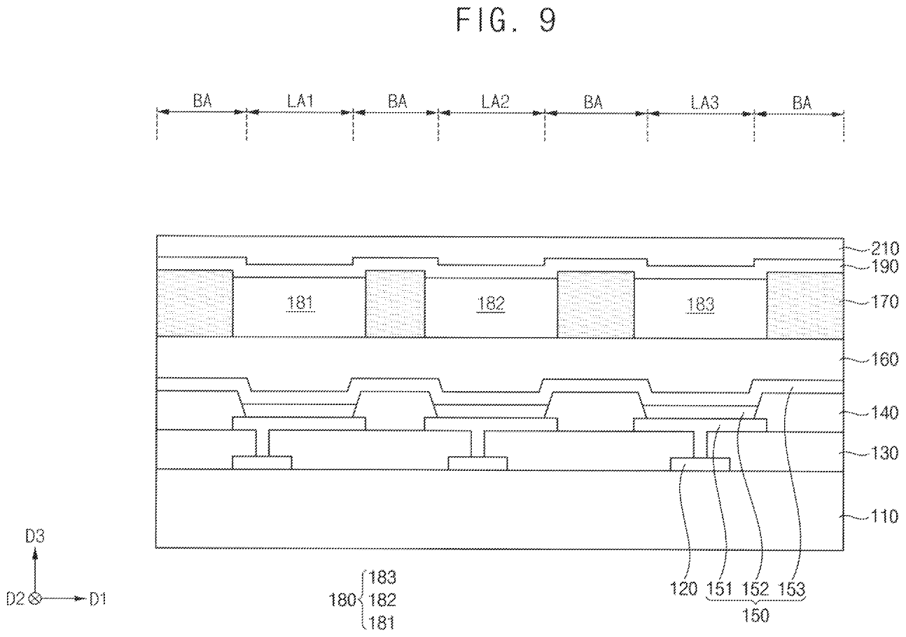

The bank layer 170 may have a first opening area OP1, a second opening area OP2, and a third opening area OP3. The first opening area OP1 may overlap the first light emitting area LA1, the second opening area OP2 may overlap the second light emitting area LA2, and the third opening area OP3 may overlap the third light emitting area LA3. Each of the first opening area OP1, the second opening area OP2, and the third opening area OP3 may receive an ink composition in the process of forming a color conversion layer (e.g., the color conversion layer 180 of FIG. 9).

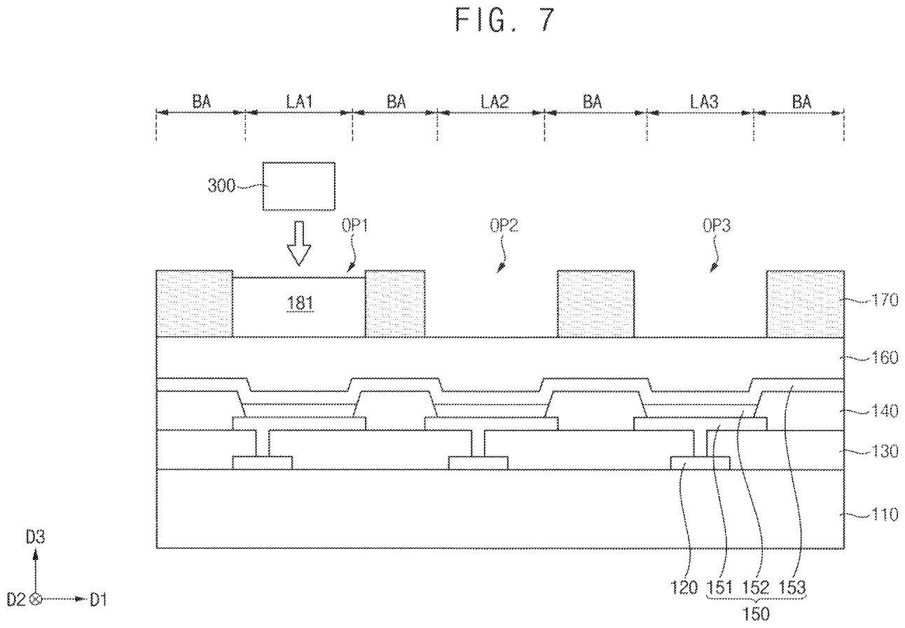

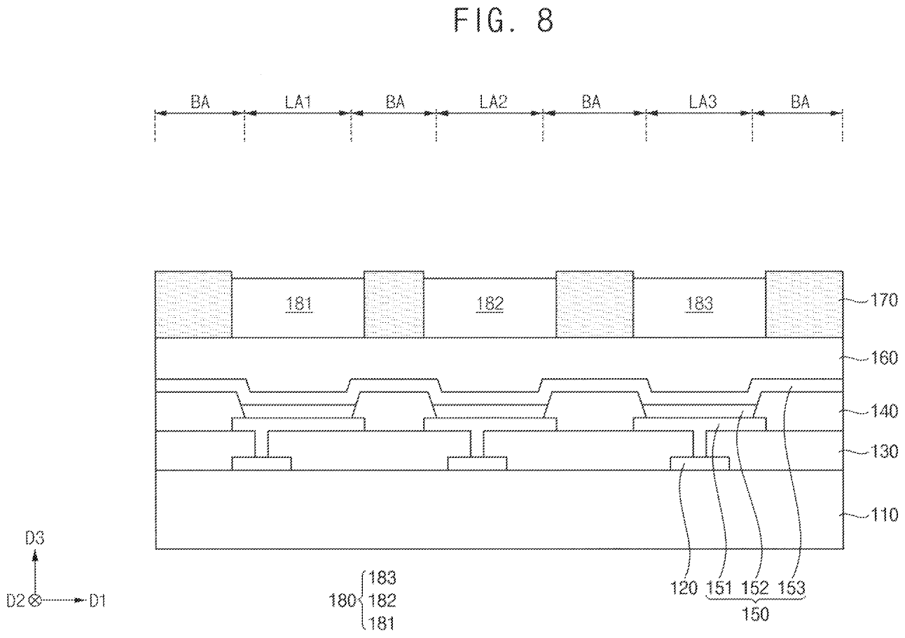

Referring to FIGS. 7 and 8, an inkjet apparatus 300 may drop the ink composition onto the first opening area OP1. Here, the ink composition may be a material for forming the color conversion layer.

The inkjet apparatus 300 may repeatedly drop the ink composition onto the first opening area OP1 to form the first color conversion pattern 181. In addition, the inkjet apparatus 300 may repeatedly drop the ink composition onto the second opening area OP2 to form the second color conversion pattern 182. In addition, the inkjet apparatus 300 may repeatedly drop the ink composition onto the third opening area OP3 to form the transmission pattern 183. Accordingly, the color conversion layer 180 including the first color conversion pattern 181, the second color conversion pattern 182, and the transmission pattern 183 may be formed on the encapsulation structure 160.

Referring to FIG. 9, the capping layer 190 may be formed on the color conversion layer 180 and the bank layer 170. The capping layer 190 may be entirely formed in the first light emitting area LA1, the second light emitting area LA2, and the third light emitting area LA3 and the light blocking area BA. The capping layer 190 may be formed using a silicon compound. In an embodiment, the silicon compound may include silicon nitride, silicon oxynitride, and/or the like.

The low refractive index layer 210 may be formed on the color conversion layer 180. The low refractive index layer 210 may be entirely formed in the first light emitting area LA1, the second light emitting area LA2, and the third light emitting area LA3 and the light blocking area BA. For example, the low refractive index layer 210 may be formed using an organic material.

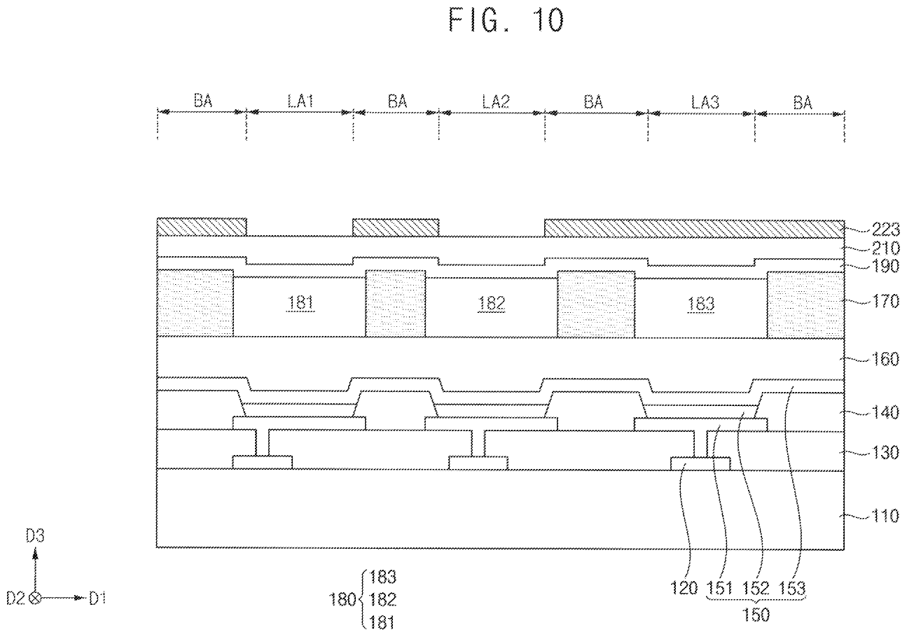

Referring to FIG. 10, the third color filter 223 may be formed on the low refractive index layer 210. A first portion of the third color filter 223 may overlap the third light emitting area LA3, and a second portion of the third color filter 223 may overlap the light blocking area BA.

The third color filter 223 may be a blue color filter that transmits blue light. For example, the third color filter 223 may be formed from a blue pigment and/or a color filter composition including a blue pigment.

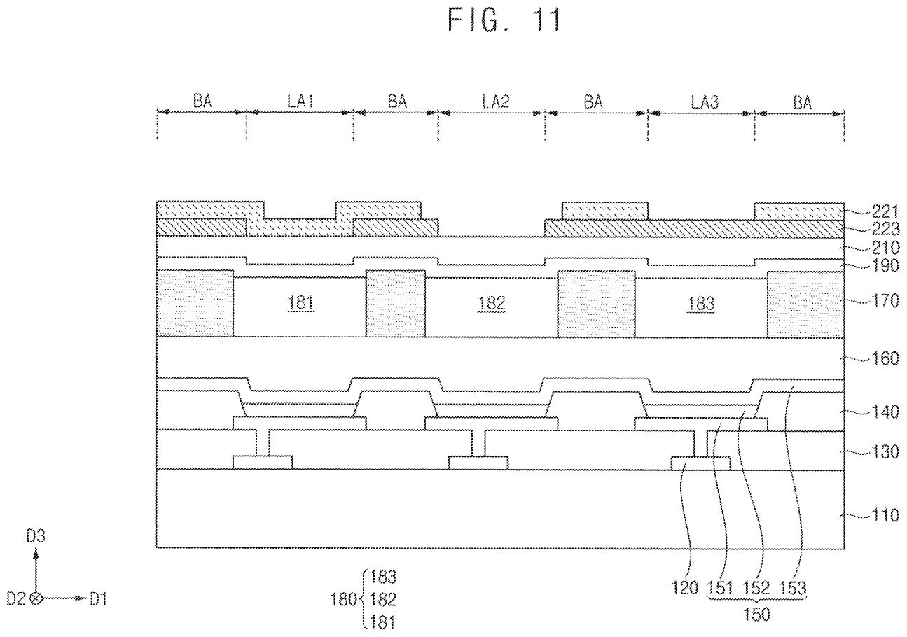

Referring to FIG. 11, the first color filter 221 may be formed on the low refractive index layer 210 and the third color filter 223. A first portion of the first color filter 221 may overlap the first light emitting area LA1, and a second portion may partially overlap the light blocking area BA.

The first color filter 221 may be a red color filter that transmits red light. For example, the first color filter 221 may be formed from a red pigment and/or a color filter composition including a red pigment.

Referring to 12, the second color filter 222 may be formed on the low refractive index layer 210 and the first color filter 221. A first portion of the second color filter 222 may overlap the second light emitting area LA2, and the second portion may partially overlap the light blocking area BA.

The second color filter 222 may be a green color filter that transmits green light. For example, the second color filter 222 may be formed from a green pigment and/or a color filter composition including a green pigment.

In some embodiments, the third color filter 223, the first color filter 221, and the second color filter 222 may be sequentially formed on the low refractive index layer 210. However, the configuration of the present disclosure is not limited thereto, and the first color filter 221, the second color filter 222, and the third color filter 223 may be formed or stacked in various suitable orders.

Accordingly, the color filter layer 220 including the first color filter 221, the second color filter 222, and the third color filter 223 may be formed on the low refractive index layer 210.

Referring back to FIG. 2, the passivation layer 230 may be formed on the color filter layer 220. The passivation layer 230 may be entirely formed in the first light emitting area LA1, the second light emitting area LA2, and the third light emitting area LA3 and the light blocking area BA. The passivation layer 230 may cover the color filter layer 220. For example, the passivation layer 230 may be formed using an organic material or an inorganic material.

Accordingly, the display device 1000 illustrated in FIG. 2 may be manufactured.

Hereinafter, an effect of embodiments of the present disclosure will be further described.

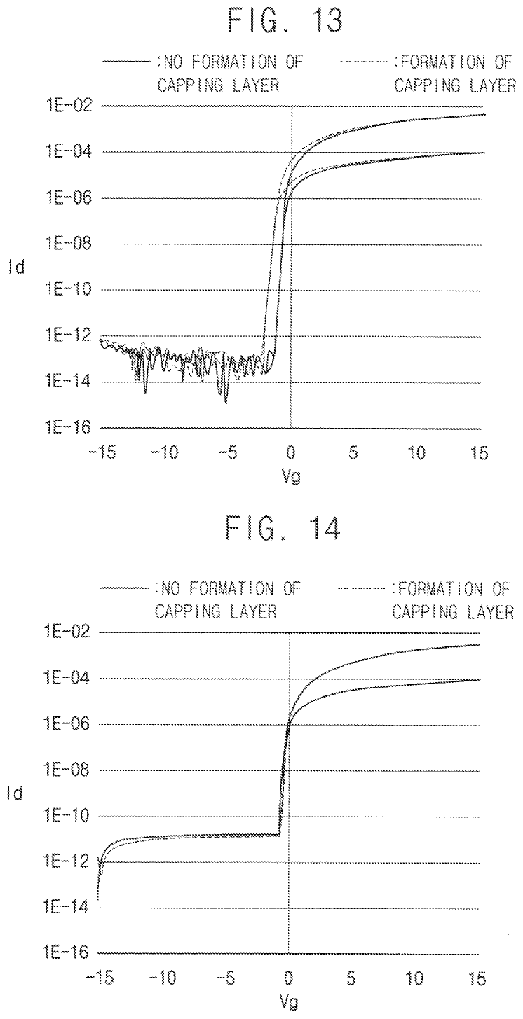

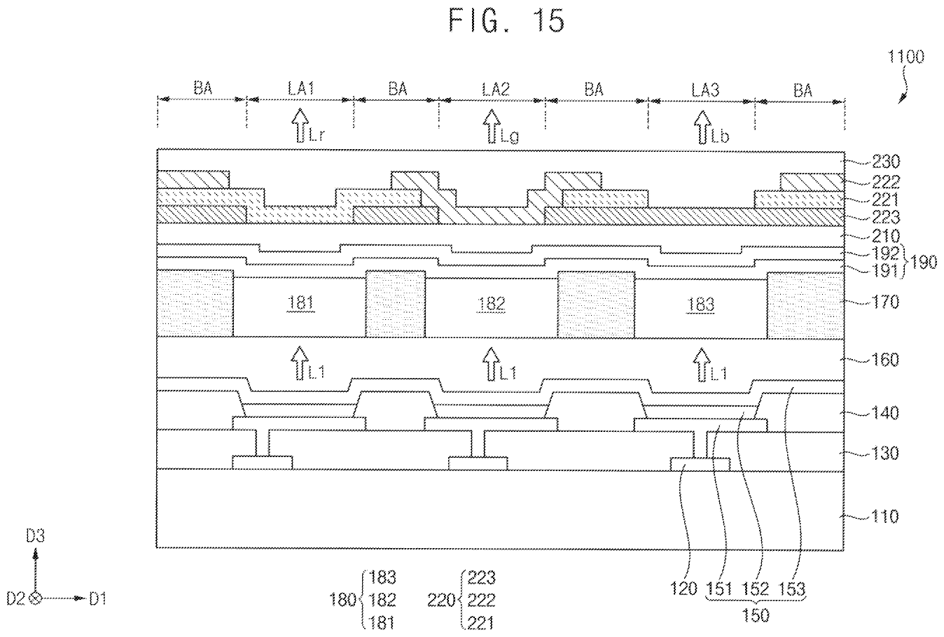

FIG. 13 is a diagram illustrating a change amount of a threshold voltage of a thin film transistor according to a comparative example. FIG. 14 is a diagram illustrating a change amount of a threshold voltage of a thin film transistor according to an embodiment.

In a comparative example and an example, a thin film transistor of the display device 1000 was manufactured using a metal oxide semiconductor including indium zinc gallium oxide (IGZO). A capping layer was manufactured using silicon nitride (SiNx). A thickness of the capping layer was about 400 nm. Under the above conditions, an amount of change in a threshold voltage of the thin film transistor according to whether or not the capping layer is formed was measured.

TABLE 1

| | Hydrogen | Hydrogen | Total | Threshold |
|---|---|---|---|---|
| | content | content | hydrogen | voltage |
| | of N—H | of Si—H | content | change |
| | bond (at %) | bond (at %) | (at %) | (V) |
| Example | 13.5 | 0.8 | 14.3 | +0.03 |
| Comparative | 22.0 | 1.7 | 23.7 | −0.64 |
| example | | | | |

Table 1 shows the amount of change in the threshold voltage of the thin film transistor according to the hydrogen content of the N—H bond, the hydrogen content of the Si—H bond, and the total hydrogen content of the capping layer in the example and the comparative example.

As a result, when the condition of the comparative example are satisfied, the amount of change in the threshold voltage of the thin film transistor depending on whether or not the capping layer is formed was measured to be about −0.64 V (see FIG. 13). On the other hand, when the condition of the above the example are satisfied, the amount of change in the threshold voltage of the thin film transistor depending on whether or not the capping layer is formed was measured to be about +0.03 V (see FIG. 14).

A fact that the amount of change in the threshold voltage of the thin film transistor satisfying the condition of the example is smaller than the amount of change in the threshold voltage of the thin film transistor satisfying the condition of the comparative example may be confirmed. Accordingly, a fact that the thin film transistor satisfying the condition of the example is improved reliability than the thin film transistor satisfying the condition of the comparative example may be confirmed.

FIG. 15 is a cross-sectional view illustrating a display device according to another embodiment.

Referring to FIG. 15, the display device 1100 according to another embodiment of the present disclosure may include a substrate 110, a driving element 120, an insulating structure 130, a pixel defining layer 140, a light emitting element 150, an encapsulation structure 160, a bank layer 170, a color conversion layer 180, a capping layer 190, a low refractive index layer 210, a color filter layer 220, and a passivation layer 230. However, the display device 1100 described with reference to FIG. 15 may be substantially the same as or similar to the display device 1000 described with reference to FIG. 2 except for the capping layer 190. Hereinafter, overlapping descriptions may not be repeated.

The capping layer 190 may be on the bank layer 170 and the color conversion layer 180. In an embodiment, the capping layer 190 may have the same thickness along the profile of each of the bank layer 170 and the color conversion layer 180.

The capping layer 190 may include a plurality of passivation layers. In an embodiment, the capping layer 190 may include a first passivation layer 191 including a metal oxide and a second passivation layer 192 including a silicon compound and on the first passivation layer 191. The first passivation layer 191 may serve to prevent or reduce the diffusion of hydrogen of the second passivation layer 192 into the driving element 120. The second passivation layer 192 may serve to prevent or reduce permeation of moisture into the color conversion layer 180 in order to prevent or reduce deterioration of the color conversion layer 180.

For example, the metal oxide may include aluminum oxide (Al₂O₃), titanium oxide (TiO₂), tantalum oxide (Ta₂O₅), hafnium oxide (HfO₂), zinc oxide (ZnO₂), and/or the like. In addition, the silicon compound may include silicon oxide, silicon nitride, silicon oxynitride, silicon oxycarbide, and/or the like. Each of the foregoing may be used alone or in combination with each other.

In an embodiment, the first passivation layer 191 may include aluminum oxide, hafnium oxide, and/or the like, and the second passivation layer 192 may include silicon nitride, silicon oxynitride, and/or the like. Each of the foregoing may be used alone or in combination with each other.

A thickness of the first passivation layer 191 may be different from a thickness of the second passivation layer 192. In an embodiment, the thickness of the second passivation layer 192 may be greater than the thickness of the first passivation layer 191. For example, the thickness of the first passivation layer 191 may be about 10 nm or less, and the thickness of the second passivation layer 192 may be about 500 nm or less.

The first passivation layer 191 may be formed by plasma enhanced chemical vapor deposition (PECVD), and the second passivation layer 192 may be formed by atomic layer deposition (ALD). The atomic layer deposition method may have a relatively slow deposition rate compared to the plasma chemical vapor deposition method. Therefore, as described above, the thickness of the second passivation layer 192 may be greater than the thickness of the first passivation layer 191.

The present disclosure can be applied to various suitable display devices that may include a display device. For example, the present disclosure can be applied to high-resolution smartphones, mobile phones, smart pads, smart watches, tablet PCs, in-vehicle navigation systems, televisions, computer monitors, notebook computers, and/or the like.

The foregoing is illustrative of embodiments of the present disclosure and is not to be construed as limiting thereof. Although a few embodiments have been described, those skilled in the art will readily appreciate that many modifications are possible in the embodiments without materially departing from the spirit and scope of the present disclosure. Accordingly, all such modifications are intended to be included within the scope of the present disclosure as defined by the appended claims, and equivalents thereof. Therefore, it is to be understood that the foregoing is illustrative of various embodiments and is not to be construed as limited to the disclosed embodiments, and that modifications to the disclosed embodiments, as well as other embodiments, are intended to be included within the scope of the appended claims, and equivalents thereof.

What is claimed is:

1. A display device comprising:
a substrate comprising a first light emitting area, a second light emitting area, and a third light emitting area, and a light blocking area surrounding the first light emitting area, the second light emitting area, and the third light emitting area;
a driving element on the substrate;
a light emitting element respectively on the driving element in each of the first light emitting area, the second light emitting area, and the third light emitting area and electrically connected to the driving element;
a color conversion layer comprising a first color conversion pattern on the light emitting element in the first light emitting area, a second color conversion pattern on the light emitting element in the second light emitting area, and a transmission pattern on the light emitting element in the third light emitting area; and
a capping layer on the color conversion layer, the capping layer comprising a silicon compound,
wherein a ratio of a hydrogen content of an N—H bond to a hydrogen content of a Si—H bond of the capping layer is about 16 or more.

2. The display device of claim 1, wherein the hydrogen content of the Si—H bond of the capping layer is about 0.8 atomic percent (at %) or less.

3. The display device of claim 1, wherein a total hydrogen content of the capping layer is about 14.3 atomic percent (at %) or less.

4. The display device of claim 1, wherein the silicon compound comprises at least one selected from the group consisting of silicon nitride (SiNₓ) and silicon oxynitride (SiON).

5. The display device of claim 1, further comprising:
a color filter layer on the color conversion layer, the color filter layer comprising a first color filter, a second color filter, and a third color filter overlapping the first color conversion pattern, the second color conversion pattern, and the transmission pattern, respectively.

6. The display device of claim 5, further comprising:
a passivation layer on the color filter layer, the passivation layer comprising at least one selected from the group consisting of an organic material and an inorganic material.

7. The display device of claim 1, further comprising:
a bank layer between the first color conversion pattern and the second color conversion pattern, between the second color conversion pattern, and the transmission pattern, and overlapping the light blocking area.

8. The display device of claim 7, wherein the capping layer is located along a profile of each of the color conversion layer and the bank layer.

9. The display device of claim 1, wherein the driving element comprises a metal oxide semiconductor.

10. A display device comprising:
a substrate comprising a first light emitting area, a second light emitting area, and a third light emitting area, and a light blocking area surrounding the first light emitting area, the second light emitting area, and the third light emitting area;
a driving element on the substrate;
a light emitting element respectively on the driving element in each of the first light emitting area, the second light emitting area, and the third light emitting area and electrically connected to the driving element;
a color conversion layer comprising a first color conversion pattern on the light emitting element in the first light emitting area, a second color conversion pattern on the light emitting element in the second light emitting area, and a transmission pattern on the light emitting element in the third light emitting area; and
a capping layer comprising:
a first passivation layer on the color conversion layer, the first passivation layer comprising a metal oxide; and
a second passivation layer on the first passivation layer, the second passivation layer comprising a silicon compound.

11. The display device of claim 10, wherein the metal oxide comprises at least one selected from the group consisting of aluminum oxide (Al₂O₃), titanium oxide (TiO₂), tantalum oxide (Ta₂O₅), hafnium oxide (HfO₂), and zinc oxide (ZnO₂).

12. The display device of claim 10, wherein the silicon compound comprises at least one selected from the group consisting of silicon nitride and silicon oxynitride.

13. The display device of claim 10, wherein a thickness of the first passivation layer is different from a thickness of the second passivation layer.

14. The display device of claim 13, wherein the thickness of the second passivation layer is greater than the thickness of the first passivation layer.

15. The display device of claim 14, wherein the thickness of the first passivation layer is about 10 nm or less, and the thickness of the second passivation layer is about 500 nm or less.

16. The display device of claim 10, further comprising:
a color filter layer on the color conversion layer, the color filter layer comprising a first color filter, a second color filter, and a third color filter overlapping the first color conversion pattern, the second color pattern, and the transmission pattern, respectively.

17. The display device of claim 16, further comprising:
a third passivation layer on the color filter layer, the third passivation layer comprising at least one selected from the group consisting of an organic material and an inorganic material.

18. The display device of claim 10, further comprising:
a bank layer between the first color conversion pattern and the second color conversion pattern, between the second color conversion pattern, and the transmission pattern, and overlapping the light blocking area.

19. The display device of claim 18, wherein the capping layer is located along a profile of each of the color conversion layer and the bank layer.

20. The display device of claim 10, wherein the driving element comprises a metal oxide semiconductor.
